(19) United States
(12) Patent Application Publication
(10) Pub. No.: US 2019/0114220 A1
(43) Pub. Date: Apr. 18, 2019

(54) METHOD AND APPARATUS FOR ENHANCING DATA INTEGRITY USING DUAL ERROR DETECTION AND REPAIR PROTECTION FOR SSD

(71) Applicant: CNEX Labs, Inc., San Jose, CA (US)

(72) Inventor: Ross Stenfort, Los Altos, CA (US)

(73) Assignee: CNEX Labs, Inc., San Jose, CA (US)

(21) Appl. No.: 15/782,629

(22) Filed: Oct. 12, 2017

(51) Int. Cl. G06F 11/10; G11C 29/52; G06F 3/06; H03M 13/03

(52) U.S. Cl. CPC G06F 11/108; G11C 29/52; G06F 2212/7203; G06F 3/0619; H03M 13/03; G06F 11/1072

(57) ABSTRACT

A storage system using dual error detection and repair (“EDR”) using a host memory buffer (“HMB”) is disclosed. In one aspect, the EDR can be CRC or ECC. The storage system is able to retrieve information from an SSD and reformatting the information into a data structure based on a host based a random-access memory (“RAM”) storage configuration. After designating a portion of RAM word for storing data and another portion of RAM word for storing data EDR, the data is organized according to the RAM word configuration with EDR. Upon generating transmission EDR according to a packet structure capable of carrying data for transmission, the system is configured to discard transmission EDR and stores the data with data EDR in the RAM inside of the host upon arrival from the SSD via a bus.

### FIELD

The exemplary embodiment(s) of the present invention relates to digital computing systems. More specifically, the exemplary embodiment(s) of the present invention relates to data integrity in connection to a solid state drive (“SSD”) using host memory buffer (“HMB”).

### BACKGROUND

An SSD is a memory device capable of retaining data persistently without connecting to a power supply. The SSD uses various non-volatile memories such as NAND based flash memories and/or phase change memories to store data or digital information. With rapidly increasing storage capacity as well as access speed associated with non-volatile memory (“NVM”), SSD becomes more popular for storing non-volatile data for computing systems, such as laptop computers, desktop computers, mobile devices, tablets, servers, routers, network devices, and the like.

A conventional flash based SSD is often used to replace or substitute existing traditional hard disk drives (“HDDs”) and uses similar input and output (“I/O”) interface as traditional HDDs. For example, HDD typically employs various types of I/O access interface such as serial attached small computer system interface (“SAS”), and serial ATA (“SATA”) interface to handle logical block address (“LBA”) based storage access. Each block or sector of LBA, for example, can be configurable to have a storage capacity of 512 bytes. As such, SSDs typically use the similar I/O interfaces as HDDs.

To reduce physical dimension of SSD while increasing storage capacity, a conventional approval is to provide dynamic random access memory less (“DRAM-less”) SSD which reduces or eliminates onboard random access memories (“RAMs”) used for data buffering. For example, host memory buffer or host managed buffer (“HMB”) can scale up DRAM-less PCIe (peripheral component interconnect express) based SSD. However, a drawback associated with the HMB based SSD is that the data in HMB could be corrupted due to various reasons whereby it can cause undetectable corruptions and incorrect behaviors.

### SUMMARY

A method and system for storing information using dual error detection and repair (“EDR”) in a random access memory (“RAM”) designated as host memory buffer (“HMB”) allocated to a connected non-volatile memory device are disclosed. EDR, in one aspect, is software error detection and recovery code such as cyclic redundancy check (“CRC”) or error correction code (“ECC”). RAM, in one example, can be either dynamic RAM (“DRAM”) or static RAM (“SRAM”). In one embodiment, the process is able to retrieve information from a solid state drive (“SSD”) and reformatting the information into a data structure based on a host based a RAM storage configuration. After designating a portion of RAM word for storing data and a second portion of RAM word for storing data EDR, the data is organized according to the RAM word configuration with EDR. Upon generating transmission EDR according to a packet structure capable of carrying data for transmission, the packet is transmitted between the SSD and host. Upon arriving to the host, the data integrity associated with the packet is verified using the transmission EDR. After discarding the transmission EDR, the data with data EDR is stored in the RAM inside of the host.

Additional features and benefits of the exemplary embodiment(s) of the present invention will become apparent from the detailed description, figures and claims set forth below.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is a block diagram illustrating a system having a host computer and a non-volatile memory (“NVM”) solid state drive (“SSD”) configured to enhance data integrity using dual EDR protection in accordance with one embodiment of the present invention;

FIG. 2A is a block diagram illustrating exemplary storage systems using transmission EDR for packet transmitting and data EDR for data from various sources in accordance with one embodiment of the present invention;

FIG. 2B is a block diagram illustrating an exemplary storage system using DEP to enhance data integrity in accordance with one embodiment of the present invention;

FIG. 3 is a logic flow diagram illustrating a process of employing dual EDR protection using transmission EDR and data EDR for error detections and corrections in accordance with one embodiment of the present invention;

FIG. 4 is a block diagram illustrating an exemplary layout for NVM device capable of logically implementing dual EDR protection (“DEP”) in accordance with one embodiment of the present invention;

FIG. 5 is a block diagram illustrating a host or memory controller capable of implementing DEP in accordance with one embodiment of the present invention;

FIG. 6 is a flow diagram illustrating an SSD HMB operation for DEP in accordance with one embodiment of the present invention; and

FIG. 7 is a flow diagram illustrating a transmission EDR operation for DEP in accordance with one embodiment of the present invention.

### DETAILED DESCRIPTION

Embodiments of the present invention are described herein with context of a method and/or apparatus for enabling a digital processing unit to access memory space in an SSD using DEP.

The purpose of the following detailed description is to provide an understanding of one or more embodiments of the present invention. Those of ordinary skills in the art will realize that the following detailed description is illustrative only and is not intended to be in any way limiting. Other embodiments will readily suggest themselves to such skilled persons having the benefit of this disclosure and/or description.

In the interest of clarity, not all of the routine features of the implementations described herein are shown and described. It will, of course, be understood that in the development of any such actual implementation, numerous implementation-specific decisions may be made in order to achieve the developer's specific goals, such as compliance with application- and business-related constraints, and that these specific goals will vary from one implementation to another and from one developer to another. Moreover, it will be understood that such a development effort might be complex and time-consuming, but would nevertheless be a routine undertaking of engineering for those of ordinary skills in the art having the benefit of embodiment(s) of this disclosure.

Various embodiments of the present invention illustrated in the drawings may not be drawn to scale. Rather, the dimensions of the various features may be expanded or reduced for clarity. In addition, some of the drawings may be simplified for clarity. Thus, the drawings may not depict all of the components of a given apparatus (e.g., device) or method. The same reference indicators will be used throughout the drawings and the following detailed description to refer to the same or like parts.

The term “system” or “device” is used generically herein to describe any number of components, elements, sub-systems, devices, packet switch elements, packet switches, access switches, routers, networks, computer and/or communication devices or mechanisms, or combinations of components thereof. The term “computer” includes a processor, memory, and buses capable of executing instruction wherein the computer refers to one or a cluster of computers, personal computers, workstations, mainframes, or combinations of computers thereof.

One embodiment of the present invention discloses a storage system capable of storing information using dual EDR protection (“DEP”) in a RAM designated as HMB allocated to a connected NVM device such as SSD. EDR, in one aspect, is software error detection and recovery code such as cyclic redundancy check (“CRC”) or error correction code (“ECC”) capable of detecting and repair error(s) occurred inadvertently. RAM, in one example, can be either dynamic RAM (“DRAM”) or static RAM (“SRAM”). In one embodiment, the process is able to retrieve information from a solid state drive (“SSD”) and reformatting the information into a data structure based on a host based a RAM storage configuration. After designating a portion of RAM word for storing data and a second portion of RAM word for storing data EDR, the data is organized according to the RAM word configuration with EDR. Upon generating transmission EDR according to a packet structure capable of carrying data for transmission, the packet is transmitted between the SSD and host. Upon arriving to the host, the data integrity associated with the packet is verified using the transmission EDR. After discarding the transmission EDR, the data with data EDR is stored in the RAM inside of the host.

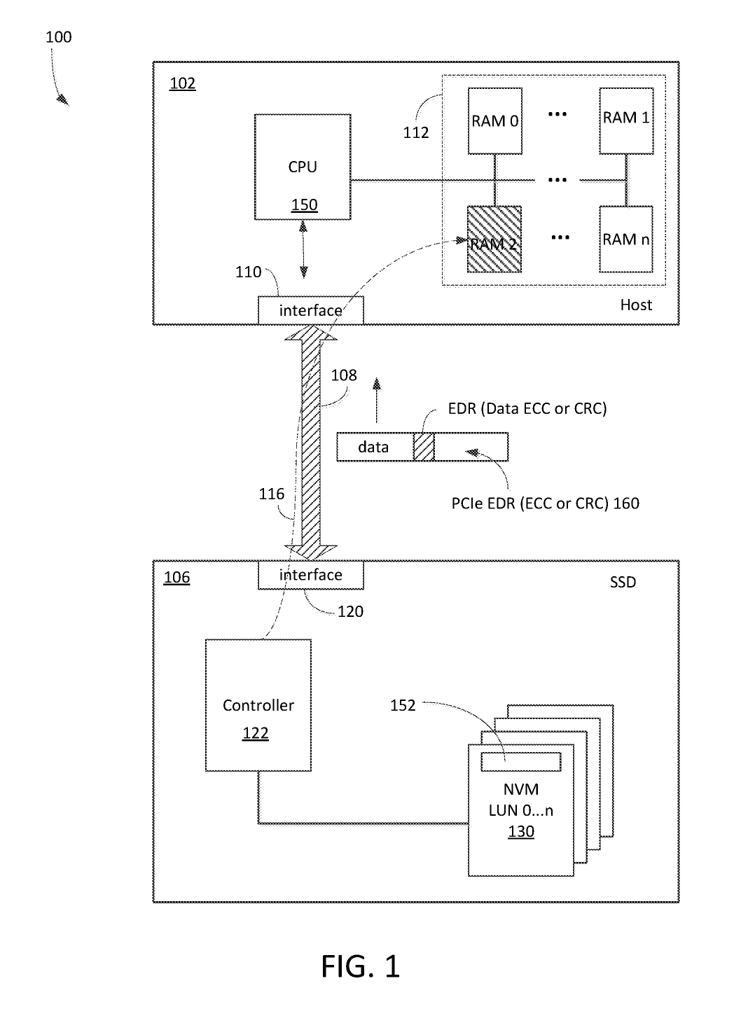

FIG. 1 is a block diagram 100 illustrating a system having a host computer and an NVM device configured to enhance data integrity using dual EDR protection (“DEP”) in accordance with one embodiment of the present invention. Diagram 100 illustrates a host or host computer 102, SSD 106, and external or peripheral bus 108. NV memory device or SSD 106, in one example, is able to store data or information persistently without connecting to an electrical power supply. SSD 106, for example, can be flash memory, phase-change memory, or magnetoresistive random-access memory (“MRAM”). It should be noted that the underlying concept of the exemplary embodiment(s) of the present invention would not change if one or more blocks (or devices) were added to or removed from diagram 100.

Host or host computer 102 includes central processing unit (“CPU”) 150, RAM storage 112, and external bus interface 110. RAM storage 112, in one example, includes multiple RAM banks, such as RAM 0, RAM 1 . . . and RAM n. Each RAM bank is organized in multiple words wherein each word has a predefined number of bits such as 128 bits or 256 bits. RAM storage 112 is a volatile memory capable of storing and retrieving data quickly as long as the power is maintained. RAM storage 112, in one aspect, can be DRAM, SRAM, and/or a combination of DRAM and SRAM. To simplify the forgoing discussion, the terms “RAM” and “DRAM” are used interchangeably.

CPU 150 is a microprocessor, processor, or controller capable of executing instructions to carryout various operations. CPU can also be referred to as a central processing unit, microprocessor, processor, microcontroller, digital signal processing component, and the like. CPU 102, in one embodiment, is configured to facilitate allocating a portion of RAM as HMB allowing a connected SSD such as SSD 106 to access host memory.

SSD or NV memory 106 includes a memory controller 122, NVM storage 130, and peripheral bus interface 120. A function memory controller or controller 122 is to manage data storage in NVM storage 130 efficiently. Controller 122, in one aspect, is configured to implement DEP using HMB or at least a portion of HMB. A function of DEP is to use a set of transmission EDR to enhance data integrity during packet transmission via bus 108. Another function of DEP is to use a set of data EDR to improve data integrity during data storage in a volatile buffer(s) such as DRAM in host 102.

EDR, in one aspect, can be CRC or ECC which is a mechanism capable of detecting error and repairing the corrupted data by correcting and/or removing the error(s). A CRC is an error-detecting code utilized in network computing devices as well as storage devices for identifying inadvertently changes to data. CRC implements in binary coding which is relatively easy to analyze mathematically, and effective at detecting common errors caused by noise occurred in, such as, transmission channels. CRC has many versions, such as CRC-1, CRC-2, and/or CRC-64. ECC, on the other hand, is an algorithm capable of expressing a sequence of numbers such that any errors which are introduced can be detected and corrected based on the remaining numbers. To simplify forgoing discussion, the terms “CRC”, “EDR”, and ECC may be used interchangeably.

NVM storage 130, in one example, can be organized into multiple logic units (“LUNs”) such as LUN 0 . . . n. LUNs, in one aspect, include multiple arrays of NAND based flash memory cells for storage. The flash memory, which generally has a read latency less than 100 microseconds (“μs”), is organized in a block device wherein a minimum access unit may be set to either four (4) Kbyte, eight (8) Kbyte, or sixteen (16) Kbyte memory capacity depending on the flash memory technology. Other types of NV memory, such as phase change memory (“PCM”), magnetic RAM (“MRAM”), STT-MRAM, or ReRAM, can also be used. As NV memory evolves such as ReRAM, byte addressable NV memory such as PCM or MRAM (Magnetic RAM) are available for storage and access. To simplify the forgoing discussion, the flash memory or flash based SSD is herein used as an exemplary NV memory for DEP. In one embodiment, LUNs can be structured or configured based on DRAM word structures as indicated by numeral 152.

Peripheral bus 108 which couples to the NV memory device is configured to facilitate data transmission between SSD 106 and host 102. In one embodiment, peripheral bus 108 is a peripheral component interconnect express (“PCIe”) bus which is capable of facilitating memory access to SSD 106 using memory addresses such as an address for a word or a byte. Word size, for example, can be one (1) byte, two (2) bytes, four (4) bytes, and/or sixteen (16) bytes. It should be noted that bus 108 can also be a high-speed peripheral bus using various different protocols, such as Thunderbolts®, Universal Serial Bus (“USB”), and the like.

Bus interface 110 or 120 is coupled with peripheral bus 108 for facilitating and/or assisting functions relating to data transfer between SSD 106 and host 102. In one embodiment, bus interface 110 or 120 is configured to implement PCIe protocol using DEP to improve data integrity. Alternatively, bus interface 110 or 120 can also provide and/or facilitate SATA protocol using DEP to enhance data integrity. In one embodiment, interfaces 110 and 120 are configured to provide EDR check as well as EDR generator.

Referring back to FIG. 1, storage system 100 configured to store information includes a host computer 102, high-speed bus 108, and SSD 106 for storing data persistently. Host computer 102, containing multiple banks of RAM, allocates a portion of RAM storage space to an external connected NVM device or SSD 106. Note that the portion of RAM can be DRAM storage dedicated to external SSD 106 for HMB.

High-speed bus 108, in one aspect, is able to transmit information or data to and/or from host computer 102 in high-speed with large bandwidth. High-speed bus 108, for example, is a PCIe cable linking between host 102 and SSD 106. It should be noted that the PCIe cable can be replaced with USB cable and/or Thunderbolt cable.

SSD 106 coupled to host computer 102 via high-speed bus 108 is configured to generate and forward a stream of packets with transmission EDR or any other types of error detection and correction code. The stream of packets includes RAM data and RAM EDR which are stored in RAM or DRAM 112 in host computer 102. SSD 106 further includes a memory controller which is able to organize information retrieved from NVM into data format in accordance with DRAM data, DRAM EDR, and transmission EDR. DRAM EDR, also referred to as data EDR, is used to maintain data integrity associated with DRAM data or data stored in DRAM and transmission EDR is used to maintain data integrity associated with packet transmission between host system 102 and SSD 106.

In operation, controller 122 is able to initialize RAM 2 in host 102 as HMB via bus 108 as indicated by dotted arrow 116. With a memory access request, controller 122 retrieves data from location 152 which may or may not be in RAM data structure. Depending on the applications, the retrieved data is organized in word format which complies with RAM 2 storage configuration. It should be noted that the data can also be SSD internal control data such as FTL table which may be retrieved from another internal component. If the retrieved data is not organized in the word format according to RAM 2 storage configuration, the retrieved data is reorganized in compliance with the RAM 2 storage configuration. The data EDR is subsequently generated for each word. After obtaining the data and data EDR, a transmission EDR or PCIe EDR is generated based on packets prior to transmission. In one aspect, data DER is CRC and transmission EDR is also CRC. After generating a data stream 160 which includes one or more packets and transmission EDR, data stream 160 is transmitted from SSD 106 to host 102. After performing an error checking and/or error correction to data stream 160 using PCIe EDR, the data with data EDR are stored in RAM 2 and PCIe EDR is discarded or striped. The data EDR is used to detect and correct error inadvertently occurred during the storage of the data.

An advantage of using DEP is that it uses embedded data EDR to detect and/or correct error(s) which could occur in RAM as HMB.

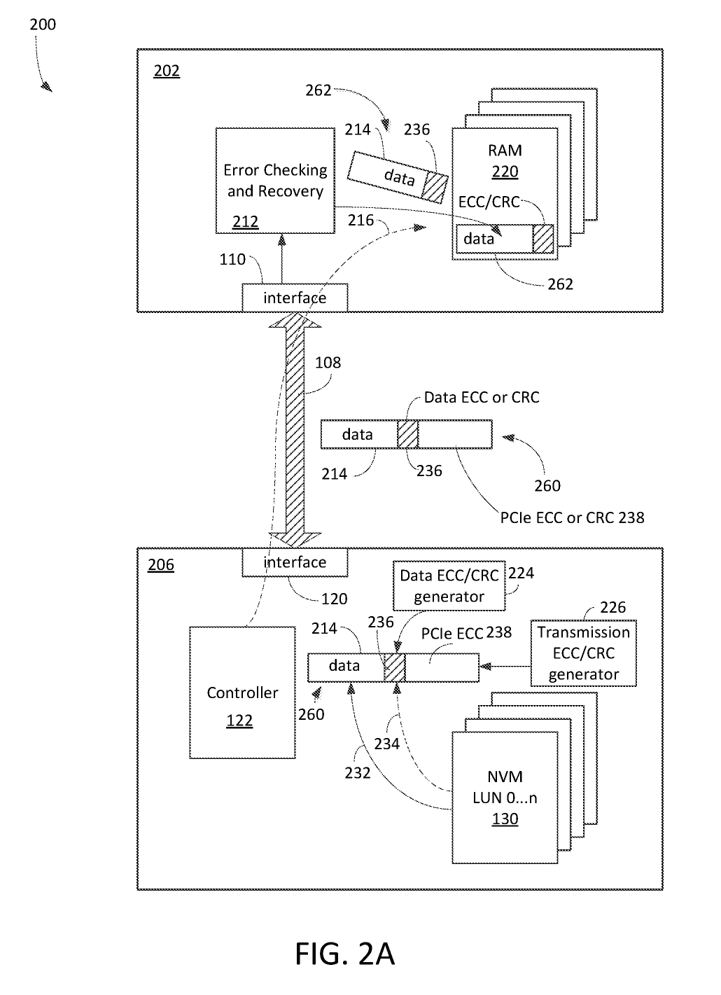

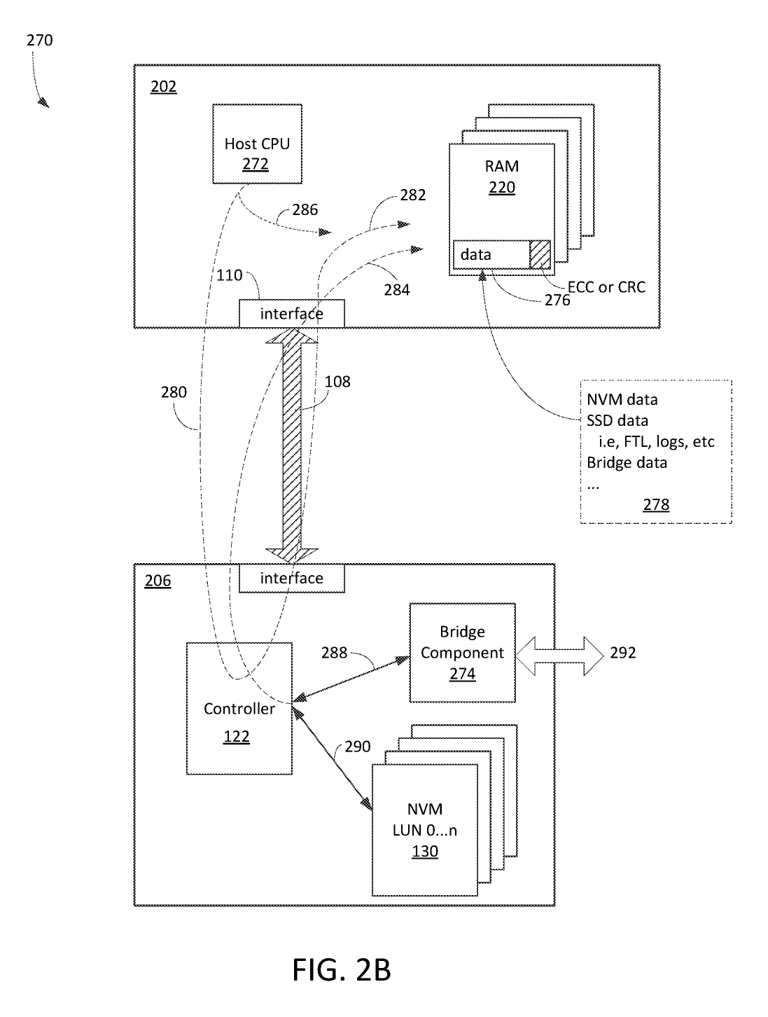

FIG. 2A is a block diagram 200 illustrating an exemplary system using transmission EDR for data transmission and data EDR for data in accordance with one embodiment of the present invention. Diagram 200 includes a host 202, SSD 206, and high-speed bus 108 wherein SSD 206 includes controller 122 and NVM 130. Host 202 includes an error checking and recovery component or circuit 212 and RAM 220 which is capable of being assigned to SSD 206 via HMB. It should be noted that the underlying concept of the exemplary embodiment(s) of the present invention would not change if one or more blocks (or devices) were added to or removed from diagram 200.

SSD 206, in one embodiment, includes data EDR generator 224 and transmission EDR generator 226 wherein data EDR generator 224 is used to generate EDR for data. Transmission EDR generator 226, in one aspect, is used to generate EDR for packet transmission. It should be noted that EDR can be any code capable of detecting and correcting error or errors. For example, EDR can be Hamming codes, Reed-Solomon codes, and the like.

Upon retrieving data 214 from NVM 130 as indicated by arrow 232, data 214 is checked to see whether data 214 contains data EDR 236. Depending on the applications, data EDR 236 can be word based, double-word based, and like. For instance, if data contains 128 bits based word, data EDR 236 will be generated based on 128 bits length of data. If data EDR 236 is not in NVM 130, data EDR 236 is generated by data EDR generator 224. After identifying data 214 and data EDR 236, PCIe EDR or transmission EDR 238 is generated by transmission EDR generator 226 based on a predefined EDR rule, such as length of packets, length of data stream, actual number of bit stream, and the like. Once PCIe EDR 238 is generated, a data packet 260 is generated.

Data packet 260 is transmitted from SSD 206 to host 202 via bus or PCIe bus 108. Upon reaching host 202, data packet 260 is fed to error checking and recovery circuit 212 to check whether any error or corruption had occurred during the transmission of data packet 260 from SSD 206 to host 202. If an error had occurred, the error may be detected and corrected based on transmission EDR or PCIe EDR 238. After transmission error checking and correction, the PCIe EDR 238 is striped or removed from data packet 260 to form data structure 262 with EDR 236. Data structure 262 is subsequently stored in RAM 220. It should be noted that data EDR 236 stored in RAM 220 can be used for error detection and error correction.

It should be noted that if the SSD embeds both data and EDR in the data packet and stores them in RAM, the EDR can be used to detect potential occurrence of errors in the RAM and correct the detected error(s).

FIG. 2B is a block diagram 270 illustrating an exemplary storage system using DEP to enhance data integrity in accordance with one embodiment of the present invention. Diagram 270 includes a host 202, SSD 206, and high-speed bus 108 wherein SSD 206 includes controller 122, NVM 130, and a bridge component 274. Host 202 includes a host CPU 272 and RAM 220 which is capable of being assigned at least a portion of it to SSD 206 as HMB. It should be noted that the underlying concept of the exemplary embodiment(s) of the present invention would not change if one or more blocks (or devices) were added to or removed from diagram 270.

SSD 206, in one aspect, includes a bridge component 274 which is used to interface with external networking devices as such Ethernet devices. A function of bridge component 274 is to pass bridge data or data traffic 292 between the Ethernet device(s) (not shown in FIG. 2B) and host 202. In one embodiment, controller 122 is able to store bridge data from bridge component 274 to RAM 220 in host 202 via connection 288 and bus 108. In another embodiment, controller 122 is able to store internal SSD control data, such as FTL tables, error logs, performance statistics, index tables, and the like, to HMB at RAM 220 as indicated by dotted block 278.

In a write operation, host CPU 272 forwards data to SSD 206 via bus 108. Upon receiving write data and requiring to be buffered, controller 122 sends the write data to HMB at RAM 220 as indicated by arrows 280-282. In one embodiment, host CPU 272 is configured to forward subsequent write packets directly to HMB at RAM 220 as indicated by arrow 286. For example, if host CPU 272 detects that portions of previously sent data has been re-sent back to HMB by controller 122, CPU 272 can directs subsequent write data (or packets) directly to HMB at RAM 220.

In a read operation, controller 122, in one embodiment, retrieves data from NVM 130 via connection 290. Upon reformatting retrieved data in compliance with RAM format, the reformatted data is forwarded to HMB at RAM 220 as indicated by arrow 284. It should be noted that EDRs are generated for both transmission packets as well as data.

For a control data storage operation, controller 122 obtains or collects SSD internal control data such as FTL table or index table and forwards the control data to HMB at RAM 220 as indicated by arrow 284. For a bridge data storage operation, controller 122 receives bridge data or external data packets 292 from an external Ethernet system or device via bridge component 274. If the bridge data needs to be buffered, controller 122 sends it to HMB at RAM 220 as indicated by arrow 284.

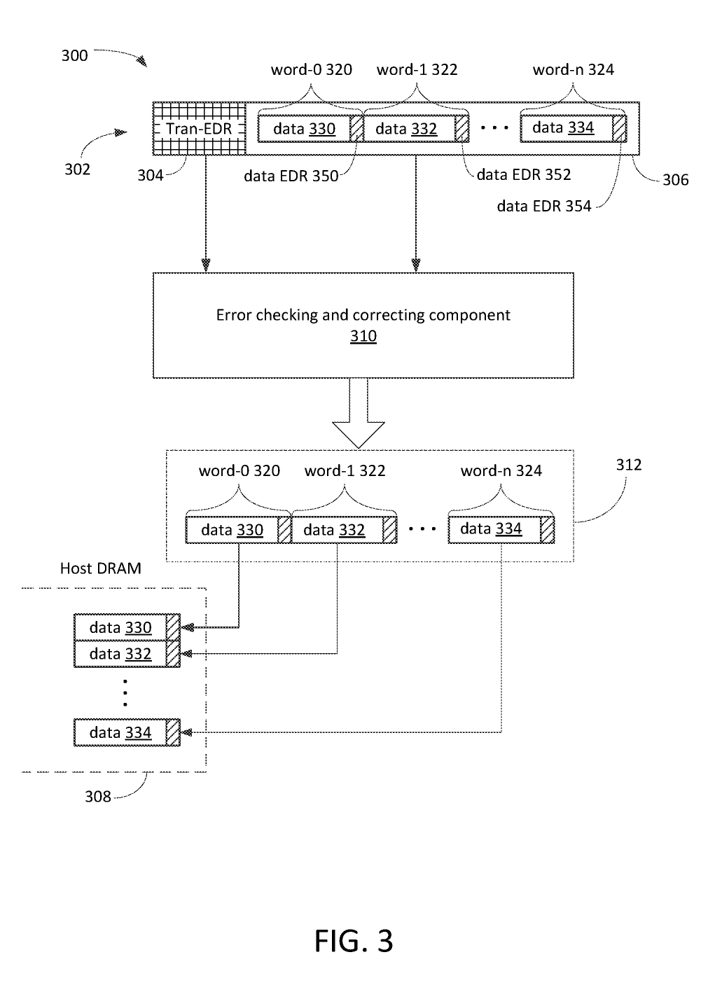

FIG. 3 is a logic flow diagram 300 illustrating a process of employing DEP using transmission EDR and data EDR for error detections and corrections in accordance with one embodiment of the present invention. Upon receiving a stream of packets 302, host or error checking and recovery circuit 310 of host identifies transmission EDR 304 and packet 306 wherein packet 306 includes word-0 320, word-1 322 . . . word-n 324. Each word includes data portion and data EDR portion. For example, word-0 320 includes data 330 and data EDR 350, and word-1 322 includes data 332 and data EDR 352. It should be noted that the underlying concept of the exemplary embodiment(s) of the present invention would not change if one or more blocks (or devices) were added to or removed from diagram 300.

Stream of packets 302 is fed to an error checking component 310 for error checking and correcting based on transmission EDR 304. It should be noted that transmission EDR 304 is specifically generated for detecting and correcting error(s) possibly occurred during the process of transmitting packets 302. After removing transmission EDR 304 from stream of packets 302, packets 306 are forwarded to storage component or circuit 312. Word-0 320, word-1 322 . . . word-n 324 are subsequently stored in host RAM 308. In one embodiment, word-0 320, word-1 322 . . . word-n 324 are formatted in compliance with RAM word structure.

An advantage of using a dual EDR protection or DEP is that it can provide protection during the data transmission and provide protection during the storage.

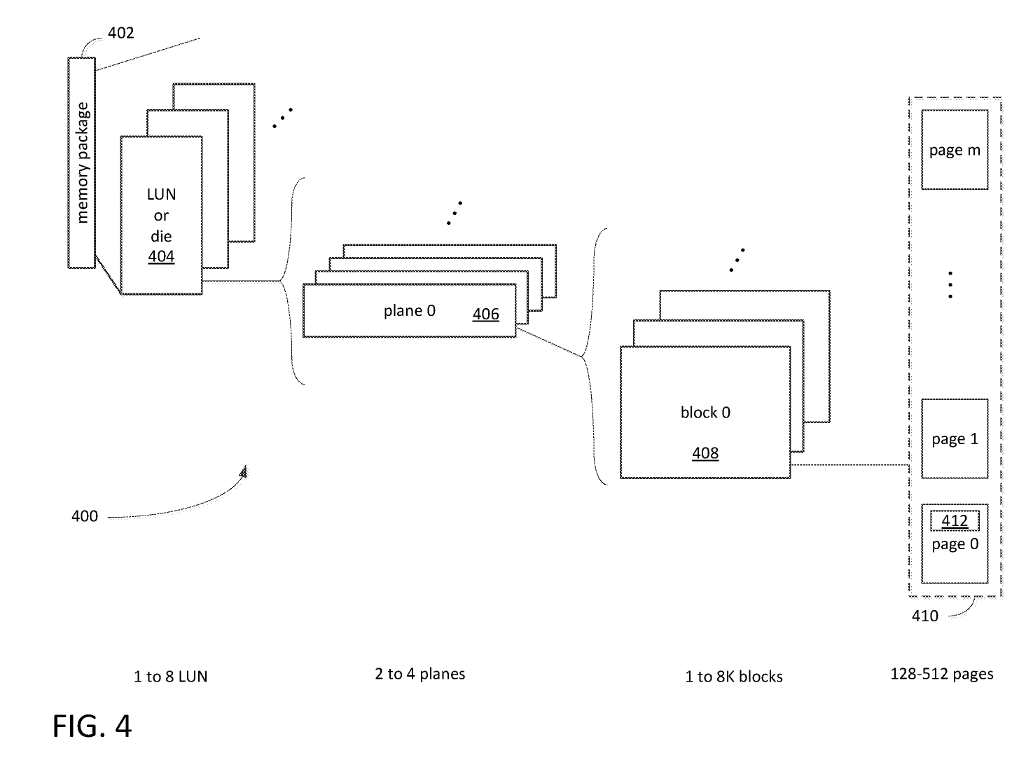

FIG. 4 is a block diagram 400 illustrating an exemplary layout for NVM device capable of logically implementing DEP in accordance with one embodiment of the present invention. Diagram 400 includes a memory package 402 which can be a memory chip containing one or more NVM dies or logic units (“LUNs”) 404. Memory package 402, in one aspect, is a flash based NVM storage that contains, for example, a hierarchy of Package-Silicon Die/LUN-Plane-Block-Flash Memory Page-Wordline configuration(s). It should be noted that the underlying concept of the exemplary embodiment(s) of the present invention would not change if one or more blocks (or devices) were added to or removed from diagram 400.

The NVM device such as a flash memory package 402, in one example, contains one (1) to eight (8) flash memory dies or LUNs. Each LUN or die 404 can be divided into two (2) to four (4) NVM or flash memory planes 406. For example, die 404 may have a dual planes or quad planes. Each NVM or flash memory plane 406 can further include multiple memory blocks or blocks. In one example, plane 406 can have a range of 1000 to 8000 blocks. Each block such as block 408 includes a range of 64 to 512 pages. For instance, block 410 includes 64 or 512 NVM pages depending on NVM technologies.

A flash memory page such as page 1, for example, has a memory capacity from 8 KBytes to 64 KBytes plus extra redundant area for management purposes such as parity bits and/or FTL tables. Each NVM block, for instance, contains from 256 to 512 NVM pages. In an operation, a flash memory block is the minimum unit of erase and a flash memory page is the minimum unit of program (or write) and read.

In one embodiment, page or pages 410 can be reconfigured into a word structure wherein a portion of word is configured to store data while another portion of word is configured to store EDR. An advantage of using DEP is that it is able to detect and correct an inadvertently bit flip in RAM when the RAM is used as HMB.

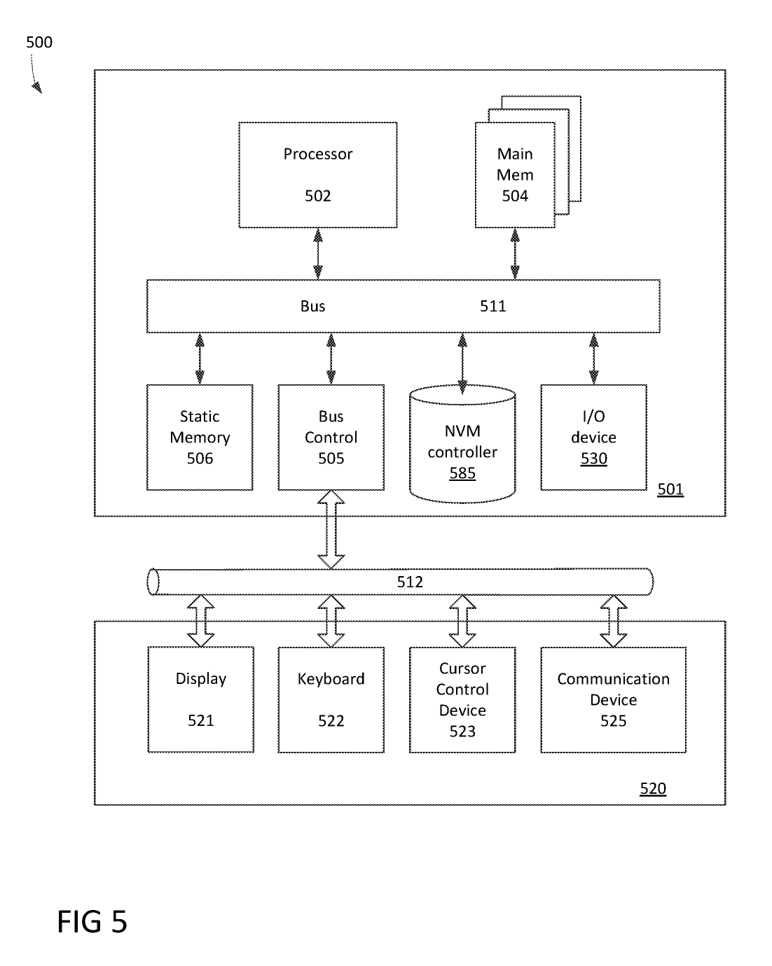

FIG. 5 is a block diagram 500 illustrating a host or memory controller capable of implementing DEP in accordance with one embodiment of the present invention. Computer system 500 includes a processing unit 501, an interface bus 511, and an input/output (“IO”) unit 520. Processing unit 501 includes a processor 502, a main memory 504, a system bus 511, a static memory device 506, a bus control unit 505, a SSD as mass storage memory 506, and NVM controller 585 for communicating with NVM devices. It should be noted that the underlying concept of the exemplary embodiment(s) of the present invention would not change if one or more blocks (circuit or elements) were added to or removed from diagram 500.

Bus 511 is used to transmit information between various components and processor 502 for data processing. Processor 502 may be any of a wide variety of general-purpose processors, embedded processors, or microprocessors such as ARM® embedded processors, Intel® Core™ Duo, Core™ Quad, Xeon®, Pentium™ microprocessor, Motorola™ 68040, AMD® family processors, or Power PC™ microprocessor.

Main memory 504, which may include multiple levels of cache memories, stores frequently used data and instructions. Main memory 504 may be RAM (random access memory), MRAM (magnetic RAM), or flash memory. Static memory 506 may be a ROM (read-only memory), which is coupled to bus 511, for storing static information and/or instructions. Bus control unit 505 is coupled to buses 511-512 and controls which component, such as main memory 504 or processor 502, can use the bus. Bus control unit 505 manages the communications between bus 511 and bus 512. Mass storage memory or SSD 106, which may be a magnetic disk, an optical disk, hard disk drive, floppy disk, CD-ROM, and/or flash memories are used for storing large amounts of data.

I/O unit 520, in one embodiment, includes a display 521, keyboard 522, cursor control device 523, and communication device 525. Display device 521 may be a liquid crystal device, cathode ray tube (“CRT”), touch-screen display, or other suitable display device. Display 521 projects or displays images of a graphical planning board. Keyboard 522 may be a conventional alphanumeric input device for communicating information between computer system 500 and computer operator(s). Another type of user input device is cursor control device 523, such as a conventional mouse, touch mouse, trackball, or other type of cursor for communicating information between system 500 and user(s).

Communication device 525 is coupled to bus 511 for accessing information from remote computers or servers through wide-area network. Communication device 525 may include a modem or a network interface device, or other similar devices that facilitate communication between computer 500 and the network.

The exemplary embodiment of the present invention includes various processing steps, which will be described below. The steps of the embodiment may be embodied in machine or computer executable instructions. The instructions can be used to cause a general purpose or special purpose system, which is programmed with the instructions, to perform the steps of the exemplary embodiment of the present invention. Alternatively, the steps of the exemplary embodiment of the present invention may be performed by specific hardware components that contain hard-wired logic for performing the steps, or by any combination of programmed computer components and custom hardware components.

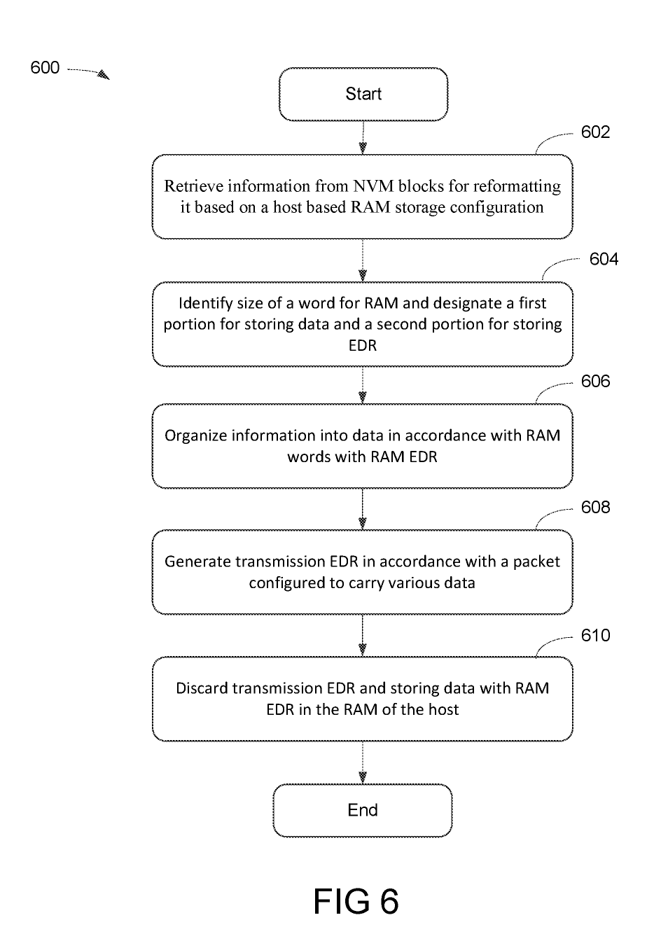

FIG. 6 is a flow diagram 600 illustrating an SSD HMB operation for DEP in accordance with one embodiment of the present invention. At block 602, a method or process for storing information using DEP is able to retrieve information from one or more NVM blocks for reformatting the information based on a host based RAM storage configuration. For example, the information is loaded from one of NVM dies or blocks to a memory controller of SSD for preparing transmission. It should be noted that reformatting data (or information) includes identifying RAM storage configuration used in host and reformatting data based on the identified RAM storage configuration.

At block 604, the process is capable of identifying the size of a word for the RAM at the host and designating a portion of word for storing RAM data and another portion of word for storing RAM EDR. For example, sixteen (16) bits per word may be determined.

At block 606, the information is organized into a data structure in accordance with RAM words plus RAM EDR prior to be transmitted to the host.

At block 608, transmission EDR is generated in accordance with a packet capable of carrying various data for packet transmission between SSD and host.

At block 610, the transmission EDR is subsequently discarded after the transmission, and the data with RAM EDR are stored in RAM upon arrival to the host via a bus. The process further allocates a portion of RAM dedicating to SSD as HMB and allows SSD to manage the allocated RAM in the host. It should be noted that the data with the transmission EDR is transmitted from SSD to host via a PCIe bus. The process implements error check using transmission EDR when the data arrives at the host. In one example, transmission EDR is used to perform an error correction to the packet. In an alternative embodiment, the process is able to transmit the data with transmission EDR from SSD to host via one of a Thunderbolt and Universal Serial Bus (“USB”) cable. In one example, a RAM error check to the data stored in RAM in response to RAM EDR. The process is able to perform an error correction in response to the RAM EDR when an error is identified during the RAM error check.

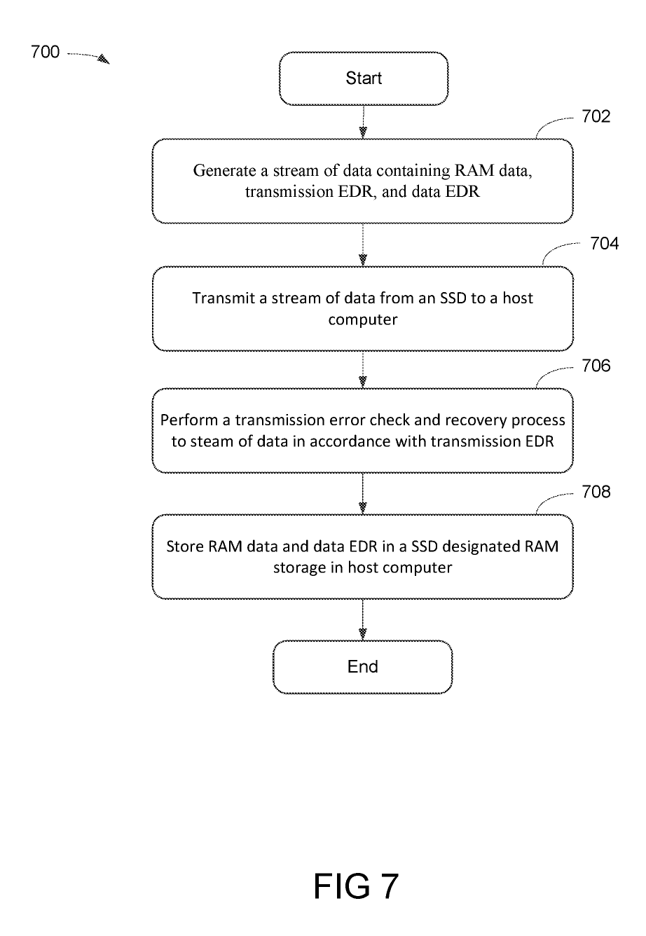

FIG. 7 is a flow diagram 700 illustrating a transmission EDR operation for DEP in accordance with one embodiment of the present invention. At block 702, a process or method for storing information in a digital processing system is able to generate a stream of data containing RAM data, transmission EDR, and data EDR.

At block 704, the stream of data is transmitted from SSD to a host computer via a high-speed external bus.

At block 706, transmission error check and recovery process are performed to the steam of data in accordance with the transmission EDR once the stream of data arrives at the host computer. Note that the digital information is transported from the SSD to the host computer via a PCIe bus.

At block 708, the RAM data and data EDR are stored in a SSD designated RAM storage in the host computer. In one aspect, after allocating a portion of RAM in the host computer to SSD, SSD is permitted to manage and control the portion of RAM. After discarding the transmission EDR, the RAM data is stored in a first predefined storage area of the RAM and the data EDR is stored in a second predefined storage area of the RAM.

While particular embodiments of the present invention have been shown and described, it will be obvious to those skilled in the art that, based upon the teachings herein, changes and modifications may be made without departing from this exemplary embodiment(s) of the present invention and its broader aspects. Therefore, the appended claims are intended to encompass within their scope all such changes and modifications as are within the true spirit and scope of this exemplary embodiment(s) of the present invention.

What is claimed is:

1. A method for storing information in a system, comprising:
retrieving information from one or more solid-state drives (“SSDs”) for reformatting the information based on a host based random-access memory (“RAM”) storage configuration;
identifying size of a word for the RAM at the host and designating a first portion of word for storing RAM data and a second portion of word for storing RAM error detection and repair (“EDR”);
organizing the information into data in accordance with RAM words with RAM EDR for transmission to the host;
generating transmission EDR in accordance with a packet configured to carry various data for packet transmission between an SSD and the host; and
discarding the transmission EDR and storing the data with RAM EDR in the RAM of the host upon arrival of the data from the SSD to the host via a bus.

2. The method of claim 1, wherein organizing the information into data in accordance with RAM words with RAM EDR includes generating cyclic redundancy check (“CRC”) for information stored in the RAM words.

3. The method of claim 1, wherein organizing the information into data in accordance with RAM words with RAM EDR includes generating error correcting code (“ECC”) for information stored in the RAM words.

4. The method of claim 1, wherein identifying size of a word for the RAM in the host includes determining word size of dynamic random access memory (“DRAM”) or word size of static random access memory (“SRAM”).

5. The method of claim 1, wherein retrieving information from one or more SSDs includes loading SSD internal control data for preparing transmission.

6. The method of claim 1, wherein retrieving information from one or more SSDs includes loading SSD flash translation layer (FTL) data for preparing transmission.

7. The method of claim 1, wherein retrieving information from one or more SSDs includes loading memory related data for preparing transmission.

8. The method of claim 1, wherein retrieving information from one or more SSDs includes loading external data packets from an external Ethernet system received by a bridge component of the SSD to a memory controller for preparing transmission.

9. The method of claim 1, further comprising allocating a portion of RAM in the host to the SSD permitting the SSD to manage the portion of RAM in the host.

10. The method of claim 9, further comprising transmitting the data with the transmission EDR from the SSD to the host via a Peripheral Component Interconnect Express (“PCIe”) bus.

11. The method of claim 10, further comprising performing an error check when the data arrives at the host in response to the transmission EDR.

12. The method of claim 11, further comprising performing an error correction in response to the transmission EDR when an error is detected.

13. The method of claim 9, further comprising transmitting the data with the transmission EDR from the SSD to the host via one of a Thunderbolt and Universal Serial Bus (“USB”) cable.

14. The method of claim 1,
wherein retrieving information from one or more SSDs includes loading the information from one of NVM dies to a memory controller of the SSD for preparing transmission; and
wherein reformatting the information includes identifying dynamic random access memory (“DRAM”) storage configuration utilized in the host and formatting the information based on the identified DRAM storage configuration.

15. The method of claim 1, wherein identifying size of a word for the RAM includes determining a sixteen (16) bits per a word.

16. The method of claim 1, further comprising performing a DRAM error check to the data stored in the DRAM in response to the RAM EDR.

17. The method of claim 16, further comprising performing an error correction in response to the RAM EDR when an error is identified during the DRAM error check.

18. A storage system configured to store information, comprising:
a host computer containing multiple banks of random-access memory (“RAM”) and configured to allocate a portion of the RAM to an external connected non-volatile memory (“NVM”);
a high-speed bus coupled to the host computer and able to transmit information to and from the host computer in high-speed with large bandwidth; and
a solid-state drive (“SSD”) coupled to the host computer via the high-speed bus and configured to generate and forward a stream of packets with transmission error detection and repair (“EDR”), wherein the stream of packets includes RAM data and RAM EDR which are stored in the RAM in the host computer.

19. The storage system of claim 18, wherein the EDR is cyclic redundancy check (“CRC”) for detecting and correcting error occurred in data.

20. The storage system of claim 18, wherein the EDR is error correcting code (“ECC”) for detecting and correcting error occurred in data.

21. The storage system of claim 18, wherein the portion of the RAM to an external connected NVM is a dynamic RAM (“DRAM”) storage dedicated to an external SSD.

22. The storage system of claim 18, wherein the portion of the RAM to an external connected NVM is static RAM (“SRAM”) storage dedicated to an external SSD.

23. The storage system of claim 18, wherein the high-speed bus is a Peripheral Component Interconnect Express (“PCIe”) cable coupled to a host.

24. The storage system of claim 23, wherein the SSD includes a memory controller which is able to organize information retrieved from an NVM into data in accordance with DRAM data, DRAM EDR, and transmission EDR.

25. The storage system of claim 24, wherein DRAM EDR is DRAM cyclic redundancy check (“CRC”) used to maintain data integrity associated with DRAM data stored in the DRAM.

26. The storage system of claim 25, wherein the transmission EDR is transmission CRC utilized to maintain data integrity associated with data transmission between the host system and the SSD.

27. The storage system of claim 18, wherein the SSD includes a memory controller which organizes information retrieved from internal SSD control data in accordance with DRAM data, DRAM EDR, and transmission EDR.

28. A method for storing information in a digital processing system, comprising:
generating a stream of data containing dynamic random-access memory (“DRAM”) data, transmission cyclic redundancy check (“CRC”), and data CRC;
transmitting the stream of data from a solid-state drive (“SSD”) to a host computer via a high-speed external bus;
performing a transmission error check and recovery process to the steam of data in accordance with the transmission CRC once the stream of data arrives at the host computer; and
storing the DRAM data and data CRC in a SSD designated DRAM storage in the host computer.

29. The method of claim 28, further comprising allocating a portion of DRAM in the host computer to the SSD permitting the SSD to manage and control the portion of DRAM.

30. The method of claim 28, wherein transmitting the stream of data includes transporting digital information from the SSD to the host computer via a Peripheral Component Interconnect Express (“PCIe”) bus.

31. The method of claim 28, further comprising discarding the transmission CRC and storing the DRAM data in a first predefined storage area of the DRAM and storing the data CRC in a second predefined storage area of the DRAM.

32. The method of claim 28, wherein storing the DRAM data includes obtaining at least a portion of data from non-volatile memory (“NVM”).

33. The method of claim 28, wherein storing the DRAM data includes obtaining at least a portion of data from internal SSD control data.

34. The method of claim 28, wherein storing the DRAM data includes obtaining at least a portion of data from an external Ethernet system received by a bridge component of the SSD.
